(19) United States
(12) Patent Application Publication
(10) Pub. No.: US 2004/0192039 A1
(43) Pub. Date: Sep. 30, 2004

(54) Method of fabricating a multi-layer circuit structure having embedded polymer resistors

(75) Inventors: Te-Yeu Su, Taoyuan (TW); Hsin-Herng Wang, Hsin-Chu (TW); Chien-Chang Huang, Taipei City (TW); Yu-Chou Yeh, Taichung City (TW)

Correspondence Address: MORGAN LEWIS & BOCKIUS LLP, 1111 PENNSYLVANIA AVENUE NW, WASHINGTON, DC, 20004, US

(73) Assignee: E Touch Corporation

(21) Appl. No.: 10/397,426

(22) Filed: Mar. 27, 2003

(51) Int. Cl. H01L 21/302; H01L 21/461

(52) U.S. Cl. 438/689

(57) ABSTRACT

A method of fabricating multi-layer circuit structure with embedded polymer resistors comprises forming a plurality of electrically conductive paths on a first substrate, forming polymer resistor paste between first and second of the electrically conductive paths on the first substrate, curing the polymer resistor paste by exposure to ultraviolet radiation to thereby solidify the shape of the polymer resistor paste, heating the polymer resistor paste to produce a first resistor, forming a plurality of electrically conductive paths on a second substrate, bonding the first and second substrates with an adhesive, wherein the first resistor is positioned between the first and second substrates.

### RELATED APPLICATIONS

This application is related in subject matter to U.S. application Ser. No. ______(Attorney Docket No. 054862-5002), filed concurrently herewith, and which is incorporated herein by reference.

### BACKGROUND OF THE INVENTION

1. Field of the Invention

The present invention relates to a method of fabricating a multi-layer circuit structure having an embedded polymer resistors

2. Discussion of the Related Art

FIG. 1 provides a cross-section of a circuit board 1 used in an electronic device, such as a cell phone, MP3 player, or personal digital assistant. The circuit board includes a circuit substrate S and a plurality of discrete components mounted on the top surface of the substrate S. The discrete components typically include passive components and active components. The discrete components may include a resistor R, a capacitor C, an inductor L, and an oscillator O. The active components may include integrated circuits (ICs), such as processors, application specific integrated circuits (ASICs), or other logic. The substrate S includes conductive traces that interconnect the components to form the electrical circuit that makes up the electronic device.

As electronic devices have become smaller, the circuit boards have also become smaller and, consequently, less space is available for mounting and interconnecting the components. Multi-layered circuit boards have been studied to reduce the surface area on the circuit board required for interconnecting the electronic components. FIG. 2 illustrates a multi-layered structure. An uppermost layer 1 may be used to mount the electronic components and an internal second layer 2 includes traces for selectively connecting the components on the uppermost layer 1. Additional layers, such as dielectric layers and GROUND layers, can also be attached to the second layer 2.

However, in the aforementioned multi-layered structure, the number of components is still limited by the area on the top surface of the substrate. A solution is to form some of the components within the multi-layer circuit board. However, there are several practical issues that must be resolved to develop a successful multi-layer circuit board. Above all, the process for forming the multi-layer board with embedded components must be efficient and inexpensive. Moreover, the components must meet the tolerance restrictions imposed by modern electronic devices.

### SUMMARY OF THE INVENTION

Accordingly, the present invention is directed to a method of fabricating multi-layer circuit structure that substantially obviates one or more problems due to limitations and disadvantages of the related art.

An object of the present invention is to provide a simple, efficient, and inexpensive method of fabricating a multi-layer circuit structure with one or more embedded polymer resistors having precisely controlled resistance values.

Another object of the present invention is to provide a method of fabricating a multi-layer circuit structure with one or more embedded polymer resistors to reduce signal path, electromagnetic interference (EMI), and/or the number of vias.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a method of fabricating multi-layer circuit structure with embedded polymer resistors comprises forming a plurality of electrically conductive paths on a first substrate, forming polymer resistor paste between first and second of the electrically conductive paths on the first substrate, curing the polymer resistor paste by exposure to ultraviolet radiation to thereby solidify the shape of the polymer resistor paste, heating the polymer resistor paste to produce a first resistor, forming a plurality of electrically conductive paths on a second substrate, bonding the first and second substrates with an adhesive, wherein the first resistor is positioned between the first and second substrates.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a cross-sectional view of a circuit board according to the related art;

FIG. 2 is a perspective view of a multi-layered circuit board according to the related art;

FIGS. 3-11 are cross-sectional views of a multi-layer circuit substrate according to an exemplary embodiment of the present invention;

FIG. 12 is a cross-sectional view of a multi-layer circuit structure according to an exemplary embodiment of the present invention; and

FIG. 13 is a flowchart of an exemplary method of fabricating a multi-layer circuit structure having embedded polymer resistors according to the present invention.

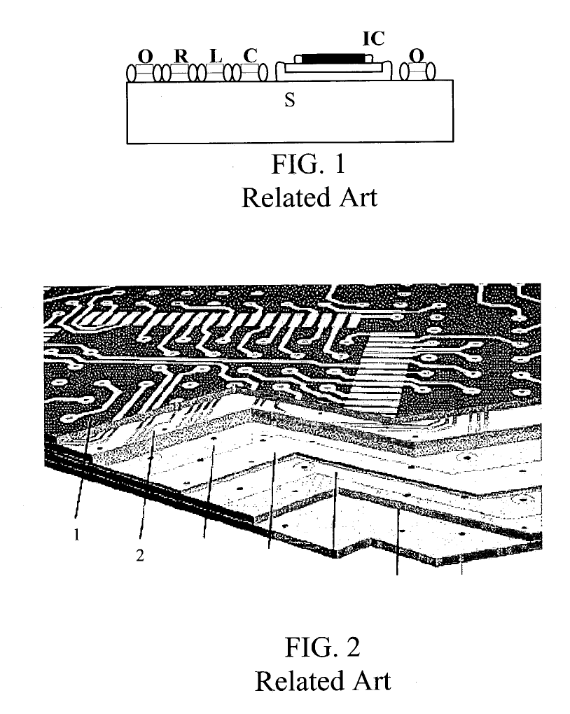

### DETAILED DESCRIPTION OF THE INVENTION

Reference will now be made in detail to the preferred embodiments of the present invention, examples of which are illustrated in the accompanying drawings.

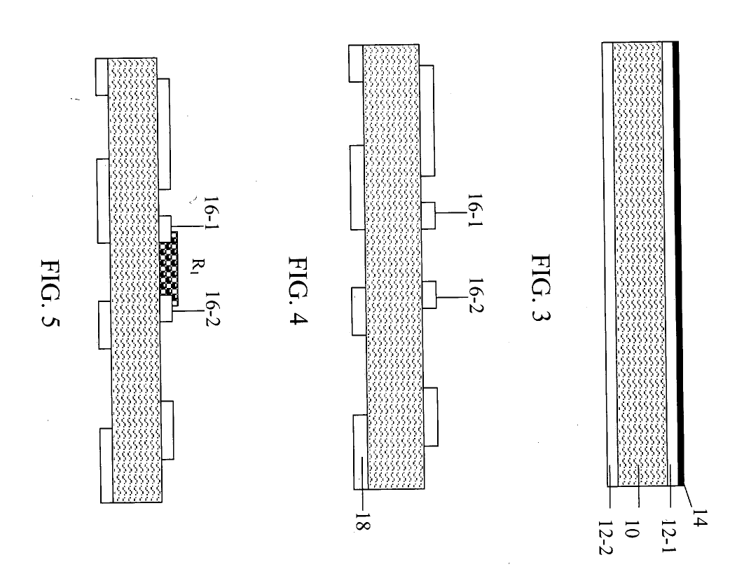

FIGS. 3-11 illustrate cross-sectional views of a component layer of a multi-layer circuit substrate according to an exemplary embodiment of the present invention. In FIG. 3, conductive layers 12-1 and 12-2 may be formed on opposing sides of a first substrate 10. Conductive layers 12-1, 12-2 may be made of a conductive material, such as metal or alloys of metal. One suitable conductive material is copper foil. Substrate 1 may be formed of an insulative material. One suitable material is an epoxy-bonded glass weave, such as FR4. Alternatively, a ceramic or polymeric material may be used.

A layer of photoresist 14 may be formed on the conductive layer 12-1 and developed to selectively pattern the conductive layers 12-1. Conductive layer 12-2 may be similarly patterned, either simultaneously with conductive layer 12-1 or in successive steps. FIG. 4 illustrates the component layer after the patterning process and after any remaining photoresist 14 is removed. As shown in FIG. 4, the component layer includes electrodes 16-1, 16-2 and traces 18 formed from the patterned conductive layers 12-1 and 12-2. FIG. 4 provides a cross-sectional illustration. It should be understood that the electrodes 16 and traces 18 extend into and/or out of the page and that other electrodes and traces may be formed on the substrate, but not shown in FIG. 4. Traces 18 provide electrically conductive paths. As will be described below, electrodes 16-1 and 16-2 provide ends between which a resistor is formed. The electrodes 16 may have a different shape than traces 18 (e.g., a different width) for some applications. However, electrodes 16 may have the same shape as traces 18 for other applications.

In FIG. 5, a first resistor R₁ may be formed between two of the electrodes 16. The first resistor R₁ may be formed from polymer resistor pastes. For example, polymer resistor pastes may be printed onto the first substrate 10, thereby forming a resistor pattern between the electrodes 16. A jet-type printer may be used to print the polymer resistor. The resistor pattern may then be processed to form the first resistor R₁. This process includes an ultraviolet (UV) radiation curing processes and a subsequent heating process, such that the UV radiation curing may solidify the shape of the resistor pattern, and the heating process activates the resistor pattern to produce the resistor. Of course, if the polymer resistor material were suitably designed, electromagnetic radiation at wavelengths other than UV may be used in curing the polymer resistor. Although only one resistor is shown in FIG. 5, multiple resistors may be printed and cured on the substrate 10. The printing may be done successively by a single printer head or simultaneously by multiple print heads. Moreover, the radiation process may be performed in a single exposure or in multiple exposures.

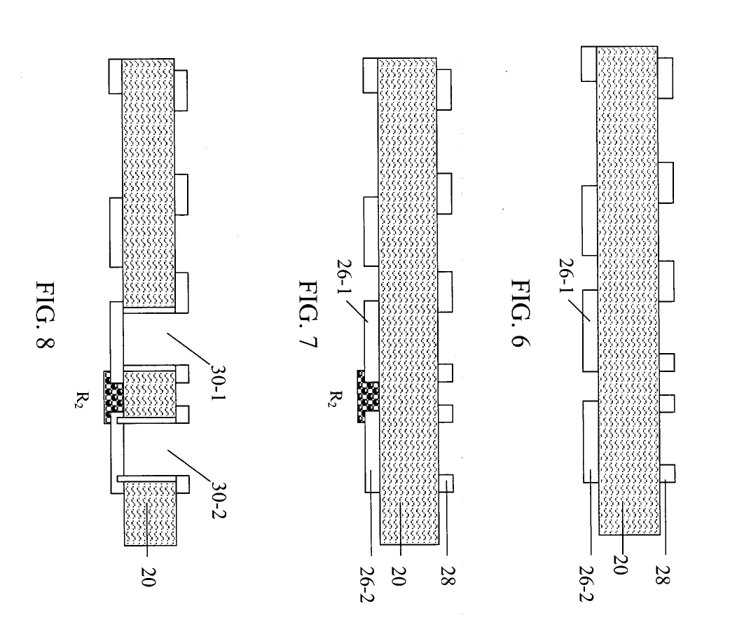

FIG. 6 illustrates a second substrate 20 with a plurality of electrodes 26-1, 26-2 formed on a bottom surface thereof. A plurality of conductive traces 28 are formed on a top surface and/or the bottom surface of the second substrate 20. The electrodes 26 and conductive traces 28 may be formed in a similar manner as the above-mentioned electrodes 16 and conductive traces 18. In FIG. 7, a second polymer resistor R₂ may be formed between two of the electrodes 26, e.g., as described above.

In FIG. 8, via holes 30-1, 30-2 may be selectively formed in the second substrate 20, and internal surfaces of the via holes 30-1, 30-2 may be coated or filled with a conductive material. Accordingly, the electrodes and conductive traces 26 and 28 on opposing surfaces of the second substrate 20 may be electrically connected with each other. For example, the via holes 30-1, 30-2 may electrically connect, respectively, to electrodes 26-1, 26-2 on the bottom surface of the second substrate 20 with conductive traces 28 on the top surface of the second substrate 20.

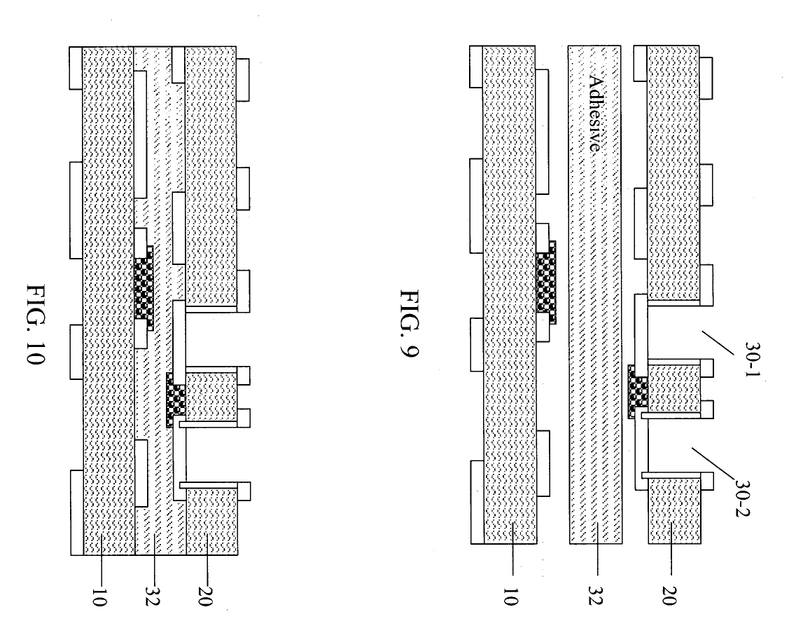

In FIG. 9, the first and second substrates 10 and 20 may be arranged, such that the resistors R₁ and R₂ are facing each other. Also, an adhesive layer 32 may be placed between the first and second substrate 10 and 20. The adhesive layer 32 may be insulative in whole or in part to prevent undesired electrical shorting between the component layers. In FIG. 10, after a bonding process, the adhesive 32 may be reflowed and the first and second substrates 10 and 20 may be securely fixed to each other with the adhesive 32 therebetween. Accordingly, the resistors R₁ and R₂ may be embedded, thereby saving an uppermost surface spaces for formation of other components.

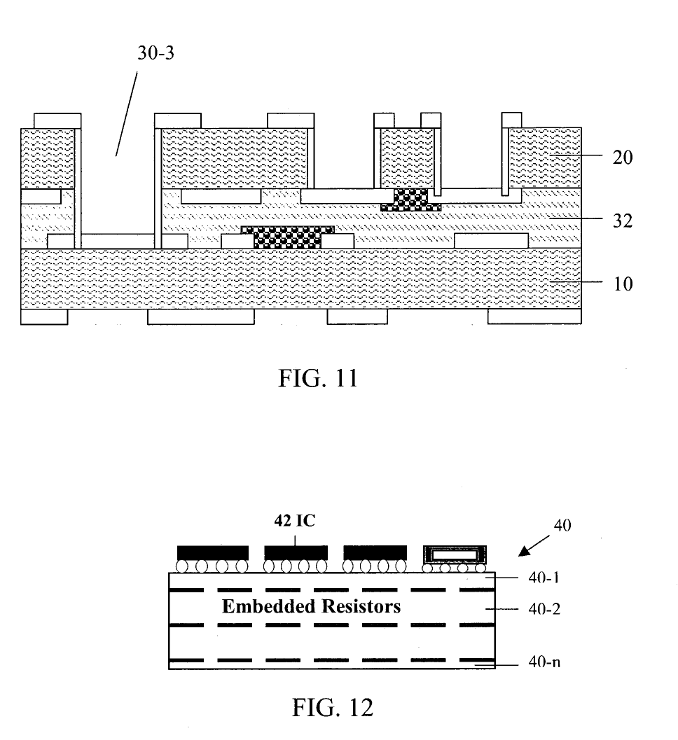

As shown in FIG. 11, an additional via hole 30-3 may be subsequently formed through the substrate 20 and adhesive material 32. Hole 30-3 may be lined or filled with conductive material to electrically connect the first and second substrates 10 and 20. For example, the via hole 30-3 may connect a conductive trace 28 of the second substrate 20 with a trace or electrode of the first substrate 10. While FIG. 11 illustrates a via hole formed after bonding, this is not required. For example, the via holes may be formed in the substrates and adhesive layer before bonding. The holes may then be aligned when the substrates are bonded. Thereafter, the aligned holes may be lined or filled with conductive material.

The processes described above in connection with FIGS. 3-11 can be used, in whole or in part, to add additional substrates to the stack. FIG. 12 is a cross-sectional view of such a multi-layered circuit board according to an exemplary embodiment of the present invention. In FIG. 12, a multi-layer structure 40 may include multiple substrate layers 40-1, 40-2, . . . 40-n. The substrate layers 40 may include embedded resistors formed in-between layers, and other components 42 formed on the uppermost surface of the multi-layered structure 40. For example, active components, such as IC chips, may be formed on a different surface than the resistors, such that the same number of components may provided on a smaller sized circuit board. The active components, such as IC chips, are connected to traces or electrodes on the top layer of the multi-layer substrate 40, e.g., by soldering, to permit electrical connection to the IC chips. It should be appreciated that the arrangement illustrated in FIG. 12 (including the embedded polymeric resistors) provides several advantages, including reduced cost of manufacture and improved electrical characteristics, including reduced electrical path length, reduced EMI.

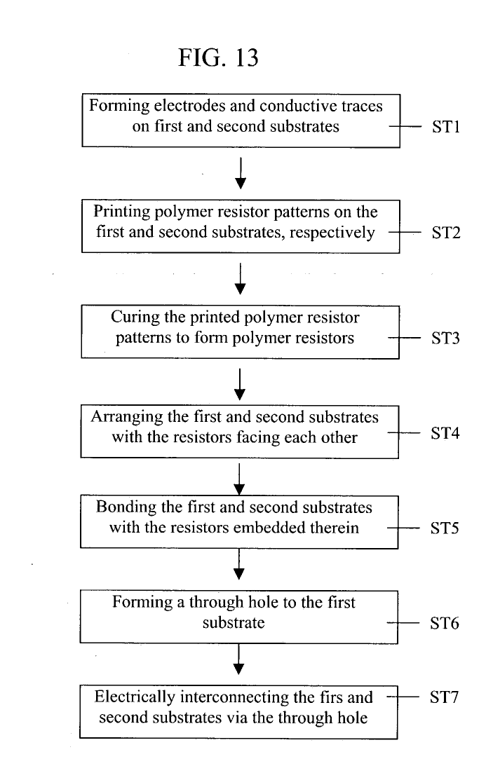

FIG. 13 is a flowchart of a method of fabricating a multi-layer substrate having embedded polymer resistors according to the present invention. As illustrated in FIG. 13, the method includes forming electrodes and conductive traces on a substrate. For example, in ST1, traces and/or electrodes may be formed on a first and second surfaces of a first substrate and on first and/or second surfaces of a second substrate. Of course, traces and/or electrodes may be formed on surfaces of additional substrates. As noted above, the electrodes and/or traces may be formed using photolithography process.

In ST2, polymer resistor patterns may be printed on the first and second substrates, and in ST3, the printed polymer resistor patterns may be cured as described above to form polymer resistors on the first and second substrates. In ST4, the first and second substrates may be arranged to face each other, wherein resistors on the first substrate face resistors on the second substrate. In ST5, the first and second substrates may be bonded to each other with the resistors embedded therein. As described above, the first and second substrate may be bonded together using an adhesive layer interposed between the first and second substrates.

Additionally, it may be desired to electrically connect portions of the first and second substrates. In ST6, a through hole may be formed in the bonded second substrate and the adhesive layer to expose the first substrate. In step ST7, electrically conductive material is applied to interconnect an electrode or trace on the first substrate to an electrode or trace on the second substrate. This may be accomplished by lining or filling the through hole with conductive material. For example, one of the electrodes formed on the first substrate may be electrically connected to one of the conductive traces on the second substrate.

It will be apparent to those skilled in the art that various modifications and variations can be made in the method of fabricating embedded polymer resistor of the present invention without departing from the spirit or scope of the invention. Thus, it is intended that the present invention cover the modifications and variations of this invention provided they come within the scope of the appended claims and their equivalents.

What is claimed is:

1. A method of fabricating a multi-layer circuit structure with embedded polymer resistors, comprising:
forming a plurality of electrically conductive paths on a first substrate;
forming polymer resistor paste between first and second of the electrically conductive paths on the first substrate;
curing the polymer resistor paste by exposure to ultraviolet radiation to thereby solidify the shape of the polymer resistor paste;
heating the polymer resistor paste to produce a first resistor;
forming a plurality of electrically conductive paths on a second substrate; and
bonding the first and second substrates with an adhesive, wherein the first resistor is positioned between the first and second substrates.

2. The method according to claim 1, wherein the step of forming the electrically conductive paths on the first substrate includes:
forming a first conductive layer on a first surface of the first substrate;
forming a first layer of photoresist pattern on the first conductive layer;
selectively removing portions of the first conductive layer through the first layer of photoresist pattern to form a first portion of the electrically conductive paths;
forming a second conductive layer on a second surface of the first substrate opposite the first surface thereof;
forming a second layer of photoresist pattern on the second conductive layer; and
selectively removing portions of the second conductive layer through the second layer of photoresist pattern to form a second portion of the electrically conductive paths.

3. The method according to claim 2, wherein the step of forming a plurality of conductive traces on a second substrate includes
forming a third conductive layer on a first surface of the second substrate;
forming a third layer of photoresist pattern on the third conductive layer;
selectively removing portions of the third conductive layer through the third layer of photoresist pattern to form a first portion of the electrically conductive paths;
forming a fourth conductive layer on a second surface of the second substrate opposite the first surface thereof;
forming a fourth layer of photoresist pattern on the fourth conductive layer; and
selectively removing portions of the fourth conductive layer through the fourth layer of photoresist pattern to form a second portion of the electrically conductive paths.

4. The method according to claim 1, wherein forming the polymer resistor paste on the first substrate comprises printing polymer resistor paste between the first and second of the electrically conductive paths on the first substrate.

5. The method according to claim 1, further comprising:
forming second polymer resistor paste between third and fourth of the electrically conductive paths on the first substrate;
curing the second polymer resistor paste by exposure to ultraviolet radiation to thereby solidify the shape of the second polymer resistor paste; and
heating the second polymer resistor paste to produce a second resistor.

6. The method according to claim 1, further comprising the step of forming a through hole in one of the first and second substrates and electrically connecting at least some of the electrically conductive paths formed on the first and second substrates.

7. The method according to claim 6, wherein the step of forming the through hole is performed before the bonding step.

8. The method according to claim 6, wherein the step of forming the through hole is performed after the bonding step.

9. The method according to claim 1, further comprising the steps of:
forming second polymer resistor paste between first and second of the electrically conductive paths on the second substrate;
curing the second polymer resistor paste by exposure to ultraviolet radiation to thereby solidify the shape of the second polymer resistor paste; and
heating the second polymer resistor paste to produce a second resistor.

10. The method according to claim 9, wherein said step of bonding comprises bonding the first and second substrates so that the first and second resistors face each other.

11. The method according to claim 1, wherein said step of bonding comprises interposing an adhesive layer between the first and second substrates.

12. The method according to claim 1, further comprising:
forming a plurality of electrically conductive paths on a third substrate;
forming second polymer resistor paste between first and second of the electrically conductive paths on the third substrate;
curing the second polymer resistor paste by exposure to ultraviolet radiation to thereby solidify the shape of the second polymer resistor paste;
heating the second polymer resistor paste to produce a second resistor; and
bonding the third substrate to one of the first and second substrates with an adhesive, wherein the second resistor is positioned between the third substrate and the one of the first and second substrates.
